(19) United States
(12) Patent Application Publication
(10) Pub. No.: US 2021/0403315 A1
(43) Pub. Date: Dec. 30, 2021

(54) SENSOR DEVICE AND METHOD FOR PRODUCING A SENSOR DEVICE

(71) Applicant: Robert Bosch GmbH, Stuttgart (DE)

(72) Inventors: Hans Artmann, Boeblingen-Dagersheim (DE); Jochen Reinmuth, Reutlingen (DE)

(21) Appl. No.: 17/295,432

(22) PCT Filed: Dec. 18, 2019
(86) PCT No.: PCT/EP2019/085940

§ 371 Date: May 19, 2021

(30) Foreign Application Priority Data
Dec. 21, 2018 (DE) 102018222715.2

(51) Int. Cl. B81B 3/00; B81C 1/00; G01L 9/00

(52) U.S. Cl. CPC B81B 3/007; B81C 1/00658; G01L 9/0051; B81B 2201/0264; B81C 2201/0132; B81B 2203/0307; B81B 2203/04; B81C 2201/0105; B81B 2203/0127

(57) ABSTRACT

A sensor device is described. The sensor device includes at least one substrate; an edge region that is disposed on the substrate and laterally delimits an inner region above the substrate; a diaphragm that is anchored on the edge structure and at least partly spans the inner region, the diaphragm encompassing in the inner region at least one region which is movable by way of a pressure and which encloses a cavity between the diaphragm and the substrate; and a first intermediate carrier that extends in the movable region below the diaphragm and is connected to the diaphragm, and in particular has at least one trench.

### FIELD

The present invention relates to a sensor device and to a method for manufacturing a sensor device.

### BACKGROUND INFORMATION

Capacitive sensors are typically manufactured by depositing conductive layers and sacrificial layers as well as a diaphragm layer that is subsequently disengaged. In most cases, the thickness of the sacrificial layer defines the spacing of the diaphragm from the counterelectrode, which is usually selected to be relatively large. Smaller spacings between diaphragm and counterelectrode are desirable in order to increase the sensitivity of such a diaphragm sensor.

German Patent Application No. DE 10 2013 213 065 describes a capacitive sensor that can encompass a counterelectrode on a substrate; a sacrificial layer having hollow spaces can be deposited on the counterelectrode, and a diaphragm can be disposed on the sacrificial layer. Etching accesses in the diaphragm can be disposed alongside the counterelectrode, and the cavities can also be usable as etching conduits. Thin diaphragms can be implemented in this manner.

### SUMMARY

The present invention provides a sensor device, and a method for manufacturing a sensor device.

Preferred refinements and embodiments of the present invention are disclosed herein.

In accordance with an example embodiment of the present invention, a sensor device and a method for manufacturing it are provided, the method for manufacturing the sensor device including that a thin diaphragm having preferably a small spacing from the counterelectrode is configurable, and it can thus exhibit increased sensitivity. The diaphragm can advantageously be manufactured from a single material; etching access holes in the movable measurement region for disengaging the diaphragm can be omitted because etching can occur laterally from the side.

According to an example embodiment of the present invention the sensor device encompasses: at least one substrate; an edge region that is disposed on the substrate and laterally delimits an inner region above the substrate; a diaphragm that is anchored on the edge structure and at least partly spans the inner region, the diaphragm encompassing in the inner region at least one region which is movable by way of a pressure and which encloses a cavity between the diaphragm and the substrate; and a first intermediate carrier that extends in the movable region below the diaphragm and is connected to the diaphragm, and in particular has at least one trench.

In accordance with an exemplifying embodiment of the sensor device of the present invention, the latter encompasses a media access having a closure, which is connected to the cavity and is disposed outside the movable region of the diaphragm and encloses a defined pressure in the cavity and in the media access.

In accordance with an exemplifying embodiment of the sensor device of the present invention, the edge structure encompasses at least one etching access conduit that is connected to the cavity.

In accordance with an exemplifying embodiment of the sensor device of the present invention, at least one electrically conductive layer constituting a first electrode is disposed on the substrate and between the substrate and the intermediate carrier, and is electrically insulated from the substrate.

In accordance with an exemplifying embodiment of the sensor device of the present invention, the intermediate carrier is fastened at contact points on the diaphragm in the movable region.

In accordance with an exemplifying embodiment of the sensor device of the present invention, the first intermediate carrier has a complete mechanical connection to the diaphragm in a subregion and in a first direction, and over an entire width in that direction.

In accordance with an exemplifying embodiment of the sensor device of the present invention, the first intermediate carrier is segmented into individual intermediate-carrier elements in a second direction, and the individual elements are embodied continuously in a first direction that deviates from the second direction.

In accordance with an exemplifying embodiment of the sensor device of the present invention, the diaphragm covers an entire region that is surrounded by the edge region.

In accordance with an exemplifying embodiment of the sensor device of the present invention, the diaphragm and/or the intermediate carrier has at least one polysilicon layer.

In accordance with an exemplifying embodiment of the sensor device of the present invention, the diaphragm and/or the intermediate carrier has at least one continuous material of the same layer thickness.

In accordance with an exemplifying embodiment of the sensor device present invention, the diaphragm encompasses at least one reference region constituting a sub-region in which the first intermediate carrier encompasses at least one support point that mechanically connects the first intermediate carrier to the substrate.

In accordance with an exemplifying embodiment of the sensor device of the present invention, the diaphragm encompasses an equal number of reference regions and movable regions, which are interconnected to one another as a half or full Wheatstone bridge.

In accordance with an exemplifying embodiment of the sensor device of the present invention, the diaphragm is electrically contacted via the edge structure.

In accordance with an exemplifying embodiment of the sensor device of the present invention, at least one of the trenches has a width in the first or second direction which is less than a height of the intermediate carrier.

In accordance with an exemplifying embodiment of the sensor device of the present invention, the spacing from the edge region to the nearest contact point is at least 10% of a planar region of extent of the diaphragm, the region of extent corresponding to a diameter in the context of a circular diaphragm or corresponding to a length of a shorter side edge in the context of a rectangular diaphragm.

According to the present invention, in the method for manufacturing a sensor device. In accordance with an example embodiment of the present invention: a substrate is furnished; at least one first sacrificial layer is disposed on the substrate; an auxiliary layer is disposed on the at least first sacrificial layer, and the auxiliary layer is patterned in such a way that at least one trench is introduced in the auxiliary layer as far as the at least first sacrificial layer, the trench being located laterally within an edge region, the edge region representing at least in part a lateral border on the substrate; a third sacrificial layer is disposed at least in the trench; a diaphragm is applied onto the auxiliary layer and at least one etching access is introduced into the diaphragm in the edge region; the at least first sacrificial layer and the third sacrificial layer laterally inside the edge region are at least partly removed by way of an etching operation through the at least one etching access; and the at least one etching access is closed off with a closure material and a defined pressure is enclosed.

The trench, or several trenches, can be located laterally inside the edge region, in that layer itself and e.g. in the intermediate carrier, i.e. in the inner region (laterally inside the edge region).

In accordance with an exemplifying embodiment of the method of the present invention, the third sacrificial layer is also disposed on the auxiliary layer, and the third sacrificial layer is patterned in such a way that orifices as far as the auxiliary layer are introduced laterally inside the edge region, and the orifices are filled with a material of the diaphragm.

In accordance with an exemplifying embodiment of the method of the present invention, before placement of the first sacrificial layer, an electrically conductive layer is applied on the substrate and is patterned laterally inside the edge region.

In accordance with an exemplifying embodiment of the method of the present invention, the etching access is connected, laterally and below the diaphragm, at least to the first and/or the third sacrificial layer.

In accordance with an exemplifying embodiment of the method of the present invention, in further steps the first conductive layer is patterned in such a way that in a first region the first conductive layer is removed and the first region delimits a first sub-region of the first conductive layer, the first conductive layer forming a first electrode in the first sub-region; the first sacrificial layer is disposed on the first conductive layer and in the first region, and the at least one first sacrificial layer is patterned in such a way that the first conductive layer is exposed in a second region and the second region is located laterally outside the first sub-region, the second region delimiting an inner region; the auxiliary layer is disposed on the at least first sacrificial layer and in the second region, and the auxiliary layer is patterned in such a way that orifices as far as the at least first sacrificial layer, which are located above the first region and in a third region, are introduced in the auxiliary layer, the third region being located laterally outside the first sub-region and the second region, the auxiliary layer forming a first intermediate carrier in the first sub-region; the third sacrificial layer is disposed on the auxiliary layer in the first and the third region, and the third sacrificial layer is patterned in such a way that the orifices are configured above the second region and above the first sub-region through the third sacrificial layer and as far as the auxiliary layer; a diaphragm is disposed on the third sacrificial layer and in the orifices in the first sub-region and in the second region, and the etching access is introduced into the diaphragm in the third region, the auxiliary layer forming in the second region the edge region in which the diaphragm is anchored, and the diaphragm forming, in the orifices in the first sub-region of the third sacrificial layer, contact points between the diaphragm and the first intermediate carrier; and the at least first sacrificial layer and the third sacrificial layer are at least partly removed by an etching operation through the etching access, the diaphragm being configured in the inner region with a region that is movable by a pressure, and the first electrode being spaced at a first spacing away from the first intermediate carrier.

In accordance with an exemplifying embodiment of the method of the present invention, a second sacrificial layer and/or fourth sacrificial layer is disposed on the first sacrificial layer and/or on the third sacrificial layer, and is patterned and removed in the same regions with the first sacrificial layer and/or with the third sacrificial layer.

In accordance with an exemplifying embodiment of the method of the present invention, the auxiliary layer is completely removed in the third region and/or in the first region (B1).

In accordance with an exemplifying embodiment of the method of the present invention, the third sacrificial layer is applied on the auxiliary layer and in its orifices. The third sacrificial layer is patterned in such a way that orifices are configured in the regions in which the auxiliary layer is to be removed in the next method step, preferably in the first and/or third region. Parts of the auxiliary layer are then removed through the orifices in the third sacrificial layer, preferably by an isotropic etching method. A fourth sacrificial layer is then deposited on the third sacrificial layer and in its orifices, in such a way that the orifices become closed off. The third and the fourth sacrificial layer are furthermore patterned in such a way that orifices at least as far as the auxiliary layer are configured.

In accordance with an exemplifying embodiment of the method of the present invention, the diaphragm is configured with a reference region which represents a sub-region of the diaphragm and in which the auxiliary layer is configured with at least one support point that connects the auxiliary layer to a region electrically separated from the conductive layer and braces the auxiliary layer on it.

In accordance with an exemplifying embodiment of the present invention, in the method for manufacturing a sensor device: a substrate is furnished and a first insulator layer is formed on the substrate; a first conductive layer is disposed on the first insulator layer and the first conductive layer is patterned in such a way that in a first region the first conductive layer is removed and the first region delimits a first sub-region of the first conductive layer, the first conductive layer forming a first electrode in the first sub-region; at least a first sacrificial layer is disposed on the first conductive layer and in the first region, and the at least one first sacrificial layer is patterned in such a way that the first conductive layer is exposed in a second region and the second region is located laterally outside the first sub-region, the second region delimiting an inner region. In addition, an auxiliary layer is disposed on the at least one sacrificial layer and in the second region, and the auxiliary layer is patterned in such a way that orifices as far as the at least one first sacrificial layer, which are located above the first region and the in a third region, are introduced into the auxiliary layer, the third region being located laterally outside the first sub-region and the second region, the auxiliary layer forming a first intermediate carrier in the first sub-region; a third sacrificial layer is disposed on the auxiliary layer in the first and the third region, and the third sacrificial layer is patterned in such a way that orifices above the second region and above the first sub-region through the third sacrificial layer and as far as the auxiliary layer are configured, and a defined pressure is enclosed.

The diaphragm can advantageously be a diaphragm layer or a layer sequence.

The sensor device can advantageously be embodied as a micromechanical component (MEMS), advantageously as a sensor.

In addition, in accordance with an example embodiment of the present invention, a diaphragm is disposed on the third sacrificial layer and in the orifices in the first sub-region and in the second region, and etching accesses are introduced into the diaphragm in the third region, the auxiliary layer forming in the second region an edge structure in which the diaphragm is anchored, and the diaphragm forms, in the orifices in the first sub-region of the third sacrificial layer, contact points between the diaphragm and the first intermediate carrier. In addition, the at least first sacrificial layer and the third sacrificial layer are at least partly removed by way of an etching operation through the etching accesses, the diaphragm being configured in the inner region with a region movable by a pressure, and the first electrode being spaced at a first spacing away from the first intermediate carrier; and the etching accesses are closed off with a closure material.

The diaphragm can advantageously also be configured as at least one diaphragm layer.

The third region can form a delimiting silicon frame constituting an etch stop.

In accordance with a preferred embodiment of the method of the present invention, a second sacrificial layer is disposed on the first sacrificial layer and/or on the third sacrificial layer, and is patterned and removed in the same regions with the first sacrificial layer and/or with the third sacrificial layer.

In such a case the second sacrificial layer can be applied onto the (at least) first sacrificial layer and upon subsequent patterning, for instance of the auxiliary layer, the latter can be removed locally at least as far as the second sacrificial layer. The two sacrificial layers can encompass the same material.

In accordance with a preferred embodiment of the method of the present invention, the auxiliary layer has, upon placement, a thickness greater than 50% of the thickness of the diaphragm.

In accordance with a preferred embodiment of the method of the present invention, several vertical trenches that are narrower than the thickness of the auxiliary layer are introduced into the auxiliary layer upon patterning of the auxiliary layer in the first region and/or in the third region, so that at least one hollow space is generated in the third sacrificial layer upon disposition of the second insulator layer in the trenches.

In accordance with a preferred embodiment of the method of the present invention, several vertical trenches that are narrower than the thickness of the auxiliary layer are introduced into the auxiliary layer upon patterning of the auxiliary layer in the first region and/or in the second region and/or in the third region and/or into the first sub-region, so that at least one hollow space is generated in the third sacrificial layer upon disposition of the second insulator layer in the trenches.

In accordance with a preferred embodiment of the method of the present invention, the auxiliary layer is completely removed in the first region.

Optionally, the auxiliary layer can also be partly or entirely removed in the region outside the third region.

Removal of the auxiliary layer is advantageously effected via narrow orifices in the third sacrificial layer, preferably by way of a gas-phase etching method. After the auxiliary layer has been dissolved out through these openings, the narrow openings in the third sacrificial layer can be closed off by the subsequently applied fourth sacrificial layer. The slits in the third sacrificial layer can be configured to be narrower than half the thickness of the fourth sacrificial layer (closure layer).

In accordance with a preferred embodiment of the method of the present invention, after the etching operation upon subsequent closure, a specific internal pressure between the diaphragm and the first conductive layer is generated.

In accordance with a preferred embodiment of the method of the present invention, the diaphragm is configured with a reference region which represents a sub-region of the diaphragm and in which the auxiliary layer is configured with at least one support point that connects the auxiliary layer to a region electrically separated from the conductive layer and braces the auxiliary layer on it. The reference region can advantageously also be configured in a separate diaphragm region. An advantageously separate reference electrode can be disposed under the reference region.

In accordance with an exemplifying embodiment of the present invention, the sensor device encompasses: a substrate; an edge structure which is disposed on the substrate and which delimits an inner region above the substrate; a diaphragm that is anchored on the edge structure and at least partly spans the inner region, the diaphragm encompassing in the inner region a region movable by a pressure; a first intermediate carrier that extends in the movable region below the diaphragm and is connected to the diaphragm by contact points; and a first electrode on the substrate, which extends under the first intermediate carrier, a first spacing between the first intermediate carrier and the first electrode being modifiable by the pressure on the movable region, a defined pressure being enclosed between the first intermediate carrier and the substrate.

At least one opening constituting an etching access can also be disposed (laterally) outside the edge region.

The sensor device can also advantageously be notable for the features and their advantages already recited in conjunction with the method, and vice versa.

The sensor device can advantageously be a capacitive sensor device, since the diaphragm along with the intermediate carrier and the first electrode can correspond to a capacitor.

In accordance with a preferred embodiment of the sensor device of the present invention, the diaphragm encompasses at least one reference region constituting a sub-region of the diaphragm in which the first intermediate carrier encompasses at least one support point that connects the first intermediate carrier to a region electrically separated from the first electrode and braces the first intermediate carrier on the separated region.

The reference region can also be constituted by a further, additional diaphragm. It is possible for the diaphragm or several diaphragms to form four diaphragm regions each having two movable diaphragms and two non-movable, fixed diaphragms (or diaphragm regions).

In accordance with a preferred embodiment of the sensor device of the present invention, the diaphragm encompasses an identical number of reference regions and movable regions, which are interconnected to one another as a Wheatstone bridge.

In accordance with a preferred embodiment of the sensor device of the present invention, the diaphragm is electrically contacted via the edge structure.

In accordance with a preferred embodiment of the sensor device of the present invention, the first intermediate carrier is segmented in a first direction into individual intermediate-carrier elements, and the individual elements are embodied continuously in a second direction that deviates from the first direction.

In accordance with a preferred embodiment of the sensor device of the present invention, an average spacing between two adjacent intermediate-carrier elements is less than a thickness of the first intermediate carrier.

In accordance with a preferred embodiment of the sensor device of the present invention, the intermediate-carrier elements are completely separated from one another.

In accordance with a preferred embodiment of the sensor device of the present invention, the diaphragm covers the entire region that is encompassed by the edge structure.

In accordance with a preferred embodiment of the sensor device of the present invention, the diaphragm is made up of at least one polysilicon layer.

In accordance with a preferred embodiment of the sensor device of the present invention, the diaphragm is made up of at least one continuous material of the same layer thickness.

In accordance with a preferred embodiment of the sensor device of the present invention, the intermediate-carrier elements are separated from one another over more than 70% of the length of the intermediate-carrier elements.

In accordance with a preferred embodiment of the sensor device of the present invention, each intermediate-carrier element is connected to the diaphragm, entirely or over at least 70%, in a second direction.

In accordance with a preferred embodiment of the sensor device of the present invention, the diaphragm is made up of at least one continuous material with no orifice.

In accordance with a preferred embodiment of the sensor device of the present invention, a hollow space is provided in the edge structure at least in one region.

In accordance with a preferred embodiment of the sensor device of the present invention, the hollow space is embodied at the level of the auxiliary layer.

The sensor device can be configured in such a way that at least one hollow space extends from the edge structure to the intermediate carrier in the region between the edge structure and the first intermediate carrier. The hollow space can furthermore be embodied at the level of the auxiliary layer, for instance as a media access.

The hollow space encompassed by the edge structure can extend over a conduit in a region outside the edge structure and can be hermetically sealed off from the environment. The diaphragm layer can extend beyond the edge structure and has an orifice there. After etching of the sacrificial layers, a cavity can be configured under the intermediate carrier and to the side thereof, which can be equivalent to an enclosed reference pressure.

A pressure sensor can advantageously be realized with the sensor device according to the present invention. Alternatively, however, any other type of sensor in which a movable diaphragm is disposed above a cavity can be realized with the above-described sensor assemblage and in particular the manufactured diaphragm sensor. It is possible, for example, to use the sensor device in the context of a rotation-rate sensor or acceleration sensor. The motion of the diaphragm or of the electrodes connected thereto can be used as an indicator of a rotation rate or an acceleration. Combining the configuration with the detection of other physical and/or chemical sensor variables is also possible. It is possible, for instance, to incorporate into the diaphragm further sensor elements such as piezoelements, temperature elements, or layers whose electrical conductivity changes as a result of the uptake or presence of predefined chemical compounds. Air mass sensors, gas sensors, or moisture sensors are possible here, for example.

Further features and advantages of embodiments of the present invention are evident from the description below with reference to the figures.

### BRIEF DESCRIPTION OF THE DRAWINGS

The present invention will be explained in further detail below with reference to exemplifying embodiments shown in the schematic Figures.

FIG. 1 is a schematic side view of a sensor device after a method step of the method for manufacturing the sensor device in accordance with an exemplifying embodiment of the present invention.

FIG. 2 is a schematic side view of a sensor device after a further method step of the method for manufacturing the sensor device in accordance with an exemplifying embodiment of the present invention.

FIG. 3 is a schematic side view of a sensor device after a further method step of the method for manufacturing the sensor device in accordance with an exemplifying embodiment of the present invention.

FIG. 4 is a schematic side view of a sensor device after a further method step of the method for manufacturing the sensor device in accordance with an exemplifying embodiment of the present invention.

FIG. 5 is a schematic side view of a sensor device after a further method step of the method for manufacturing the sensor device in accordance with an exemplifying embodiment of the present invention.

FIG. 5a is a schematic plan view of a sensor device after a further method step of the method for manufacturing the sensor device in accordance with an exemplifying embodiment of the present invention.

FIG. 6 is a schematic side view of a sensor device in accordance with an exemplifying embodiment of the present invention.

FIG. 7 is a further schematic side view of a sensor device in accordance with an exemplifying embodiment of the present invention.

FIG. 8 schematically depicts method steps of a method for manufacturing a sensor device in accordance with an exemplifying embodiment of the present invention.

FIG. 9 is a schematic side view of a sensor device in accordance with a further exemplifying embodiment of the present invention.

FIG. 10 is a schematic plan view of a sensor device in accordance with a further exemplifying embodiment of the present invention.

In the Figures, identical reference characters designate identical or functionally identical elements.

### DETAILED DESCRIPTION OF EXAMPLE EMBODIMENTS

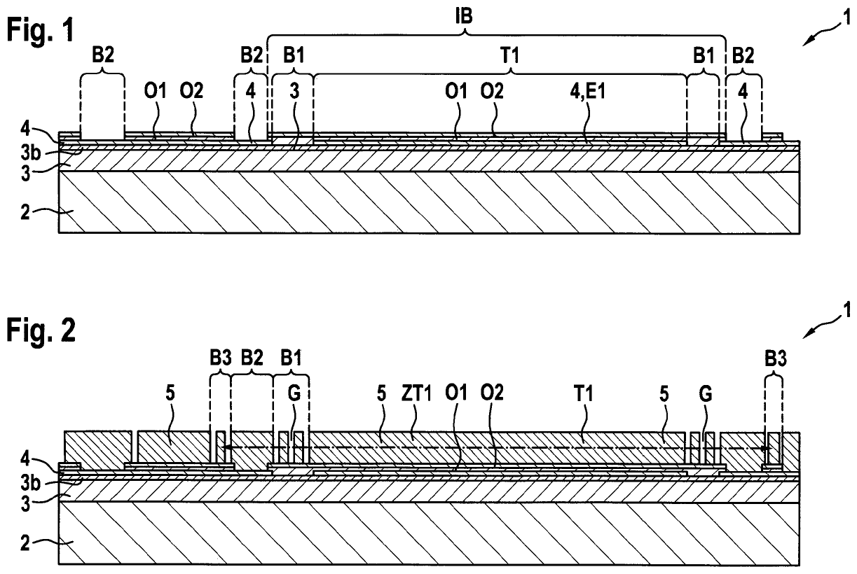

FIG. 1 is a schematic side view of a sensor device after a method step of the method for manufacturing the sensor device in accordance with an exemplifying embodiment of the present invention.

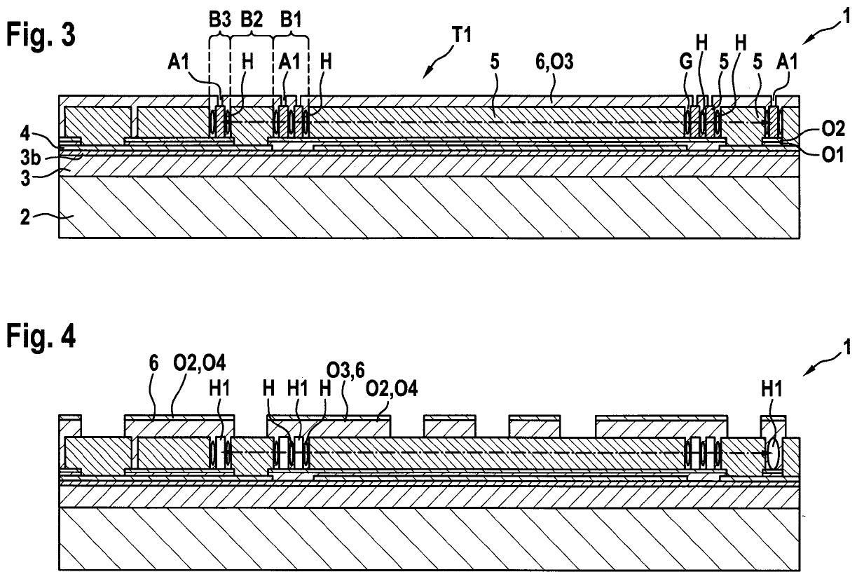

FIG. 1 shows a substrate 2 on which a first insulator layer 3 is embodied. Subsequently, a first conductive layer 4 is disposed on first insulator layer 3, and first conductive layer 4 is patterned in such a way that first insulator layer 3 becomes exposed in first region B1, first region B1 delimiting a first sub-region T1 of first conductive layer 4, such that in first sub-region T1, first conductive layer 4 forms a first electrode E1 and advantageously can also form a conductor path. First conductive path 4 can encompass a doped polysilicon layer. A first sacrificial layer O1 is furthermore disposed on first conductive layer 4 and in first region B1, and first sacrificial layer O1 was patterned in such a way that first sacrificial layer O1 is removed in a second region B2 and second region B2 is located laterally outside first sub-region T1, second region B2 delimiting an inner region IB. At a lateral outer region B22 that can be located laterally outside second region B2, first sacrificial layer O1 (or, if present, also a second sacrificial layer O2 on the latter) can be removed. Also shown in FIG. 1 is the fact that an additional insulator layer, advantageously a non-conductive layer 3b, which can also encompass several individual layers, can be present between first insulator layer 3 and first conductive layer 4. As the method proceeds, additional insulator layer 3b can serve as an etch stop which can encompass a silicon-rich nitride layer. Additional insulator layer 3b can be patterned before or after deposition of the first conductive layer. First insulator layer 3 (and additional insulator layer 3b when present) can also be patterned and equipped with orifices so that a substrate contact can be produced. A second sacrificial layer O2 can furthermore be disposed on further sacrificial layer O1 and can be patterned and removed with first sacrificial layer O1 in the same regions. First and/or second sacrificial layer O1, O2 can encompass, for example, an oxide layer (silicon oxide). Two sacrificial layers make it possible for the spacing between first electrode E1 and the subsequent elements, for instance auxiliary layer 5 of FIG. 3, to be adjusted in two steps, i.e. for example, different spacings can be generated in different regions. Auxiliary layer 5 can be embodied as a semiconductor material layer.

An insulator layer 3b can advantageously be configured below first conductive layer 4 on substrate 2 as a stop layer for an etching method, so that first insulator layer 3 is not attacked in the context of sacrificial layer etching, and under-etching of first conductive layer 4 is thus prevented. The materials used can be SiRiN, SiC, or others, because they are etched more slowly than SiO₂.

The sensor device can be configured as a pressure sensor device.

FIG. 2 is a schematic side view of a sensor device after a further method step of the method for manufacturing the sensor device in accordance with an exemplifying embodiment of the present invention.

Once the method steps as shown for example in FIG. 1 have been completed, subsequently, in accordance with FIG. 2, an auxiliary layer 5 can be disposed on first sacrificial layer O1 and in second region B2, and auxiliary layer 5 can be patterned in such a way that orifices advantageously as far as first sacrificial layer O1, or as far as second sacrificial layer O2 if it is applied on first sacrificial layer O1, are introduced into auxiliary layer 5, said orifices being located above first region B1 and in a third region B3, third region B3 being located laterally outside first sub-region T1 and second region B2, auxiliary layer 5 forming a first intermediate carrier ZT1 in first sub-region T1. In the context of the patterning of auxiliary layer 5, several vertical trenches G that are narrower than the thickness of auxiliary layer 5 can be introduced into auxiliary layer 5 in first region B and/or in third region B3.

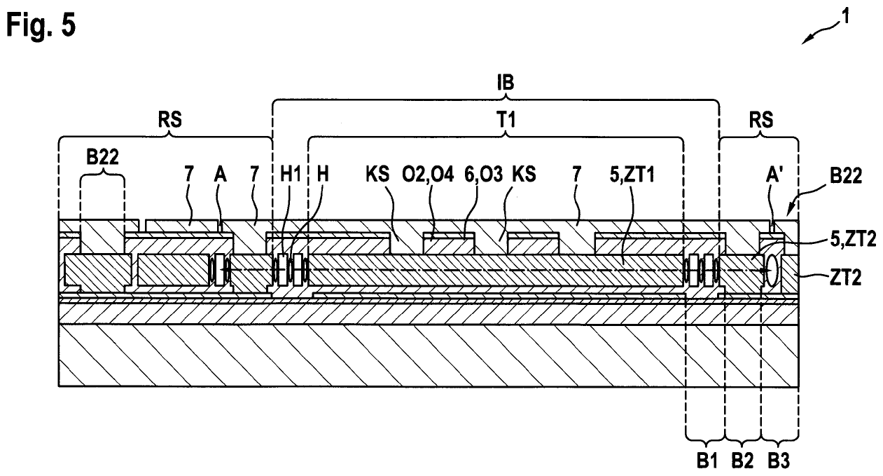

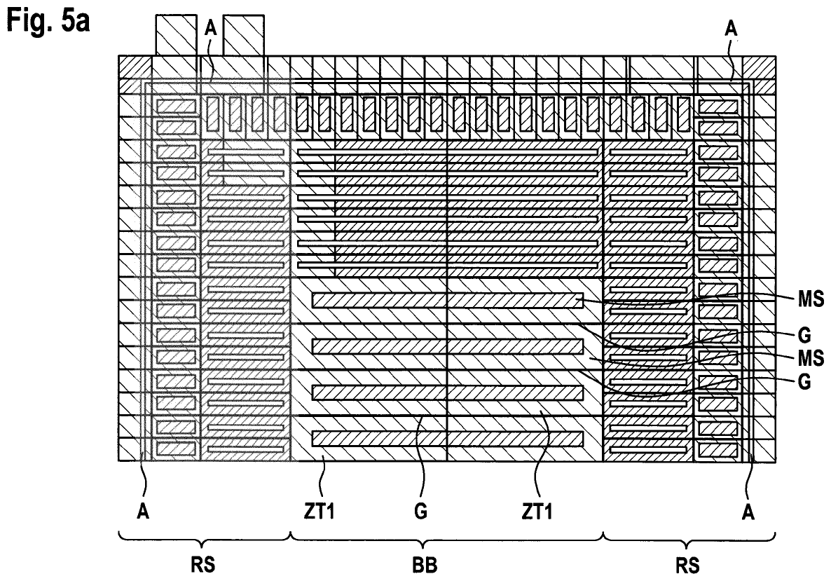

A polysilicon layer can be deposited as auxiliary layer 5. In order to enable good stiffening in individual regions, a layer thickness can be selected which is greater than 50% of the diaphragm layer thickness that is constituted in accordance with FIG. 5. A layer at least 500 nm thick is preferably deposited, in order to allow high stability to be achieved in lateral edge regions of the auxiliary region. An etching method by which vertical trenches or orifices can be generated in the auxiliary layer can preferably be used to pattern the auxiliary layer. A trenching method can preferably be used.

Thanks to trenches G and the etching access produced thereby, sacrificial layers O1 and O2 between the auxiliary layer and the first conductive layer can be made as thin as desired. The advantage of this embodiment is that after deposition of a third sacrificial layer 6 or O3, lateral hollow spaces H, through which an etching medium can propagate very rapidly, form in trenches G, thus making possible an etching access laterally next to the diaphragm that has yet to be formed, in particular by way of auxiliary layer 5, in third region B3 (see FIG. 3).

FIG. 3 is a schematic side view of a sensor device after a further method step of the method for manufacturing the sensor device in accordance with an exemplifying embodiment of the present invention.

Once the method steps as shown for example in FIG. 2 have been completed, subsequently, in accordance with FIG. 3, a third sacrificial layer 6, O3 can be disposed on auxiliary layer 5 in first region B1 and third region B3. With sufficiently narrow dimensioning of the lateral extent upon introduction of third sacrificial layer 6, O3, hollow spaces H can be configured in trenches G.

Narrow orifices A1 can furthermore be generated in third sacrificial layer 6, O3, which itself can also be configured as a sacrificial layer, for instance as an oxide layer (silicon oxide).

FIG. 4 is a schematic side view of a sensor device after a further method step of the method for manufacturing the sensor device in accordance with an exemplifying embodiment of the present invention.

Orifices A1 configured in third sacrificial layer 6, O3 in FIG. 3 can serve, with e.g. isotropic etching, to remove portions of auxiliary layer 5 under third sacrificial layer 6, O3, which can subsequently result in hollow spaces H1 in accordance with FIG. 4.

Auxiliary layer 5 can thus be completely removed in third region B3 and/or in first region B1. Orifices A1, configured as slits, can then be closed off with a further oxide deposition (silicon oxide), for instance a material of a sacrificial layer, for instance of a second sacrificial layer O2 or fourth sacrificial layer O4, and can form a large hollow space H1, optionally together with the previously generated hollow spaces H. As a result, upon subsequent disposition of the diaphragm (FIG. 5) in individual regions, a very large spacing between the diaphragm and first electrode E1, with very low capacitance, can be generated. Upon later removal of third sacrificial layer 6, O3 and of sacrificial layers O1, O2, and O4, hollow spaces H, H1 can serve as an accelerating element for better propagation of the etching medium. The choice of the regions at which these hollow spaces are configured can be used to influence the etching effect (spatial extent) and can be selected to be locally different.

In addition, third sacrificial layer 6, O3 is patterned in such a way that orifices are configured, above second region B2 (and optionally also B22, as shown in FIG. 1 and FIG. 5) and above first sub-region T1, through third sacrificial layer 6 and as far as auxiliary layer 5. A second sacrificial layer O2 or fourth sacrificial layer O4 can also be embodied on third sacrificial layer 6, O3 and can be patterned in the same regions as third sacrificial layer 6, O3.

FIG. 5 is a schematic side view of a sensor device after a further method step of the method for manufacturing the sensor device in accordance with an exemplifying embodiment of the present invention.

Once the method steps as shown for example in FIG. 4 have been completed, subsequently, in accordance with FIG. 5 a diaphragm (layer) 7 can be disposed on third sacrificial layer O3 and/or fourth sacrificial layer O4 and in the orifices in first sub-region T1 and in second region B2 (and optionally also B22), and etching accesses A, A′ can be introduced into diaphragm (layer) 7 in third region B3; in second region B2, and advantageously also laterally outside as seen from first region B1, auxiliary region 5 can form an edge structure RS in which diaphragm 7 can be anchored, and diaphragm 7 can advantageously form, in the orifices in first sub-region T1 of third sacrificial layer 6, O3 and/or fourth sacrificial layer O4, several contact points KS between diaphragm (layer) 7 and first intermediate carrier ZT1, advantageously encompassing the material of diaphragm 7. Diaphragm 7 can encompass, for example, a polysilicon layer. Edge structure RS can thus advantageously be located laterally outside those regions of diaphragm 7 which can be movable as a result of the external pressure. Edge structure RS advantageously can laterally surround diaphragm 7 at several regions. Auxiliary layer 5 can remain in the edge structure as a second intermediate carrier ZT2 that can be connected locally to electrically conductive layer 4 and to diaphragm layer 7, and can electrically contact them. A surrounding frame thereby produced, advantageously in lateral outer region B22, can serve as an etch stop outside the diaphragm suspension system of region B2.

FIG. 5 shows a section plane; laterally behind it in another section plane (not shown), for example as shown in FIG. 5a, trenches G′ can extend in the intermediate carrier between its segments from left to right, and can also extend into edge structure RS and/or can also extend through edge structure RS.

In an exemplifying embodiment, trenches G′ are located between the individual intermediate carriers ZT1 in order to “separate” them from one another. They are not visible in the section drawing of FIG. 5 since they are disposed parallel to the section that is depicted (see FIG. 5a). Each individual intermediate carrier ZT1 thus represents, together with the diaphragm region to which intermediate carrier ZT1 is connected, a boss diaphragm. More-flexible motion of the diaphragm can be achieved by way of trenches G′ that mechanically separate the intermediate carriers from one another, since finer-scale motions of the diaphragm are possible upon application of an external pressure. Provision can be made that at least two intermediate carriers ZT1 are disposed next to one another, and between them a trench G′ is provided which physically separates the two intermediate carriers (see FIG. 5a). Because trench G′ generates a sufficiently large spacing between intermediate carriers ZT1, deflection of the diaphragm cannot cause intermediate carriers ZT1 located next to one another to touch each other. Optionally, provision can also be made to introduce trenches G′ directly into auxiliary layer 5 in order to subdivide first intermediate carrier ZT1, generated by that auxiliary layer 5, into several segments spaced apart from one another.

In an alternative embodiment, provision can also be made that the trenches extend within intermediate carrier ZT1 along the dot-dash line shown in FIG. 5. What can be achieved thereby is that an etching conduit is generated through which uniform and complete etching of the sacrificial layers is made possible in order to disengage the intermediate carrier.

FIG. 5a is a schematic plan view of a sensor device after a further method step of the method for manufacturing the sensor device in accordance with an exemplifying embodiment of the present invention.

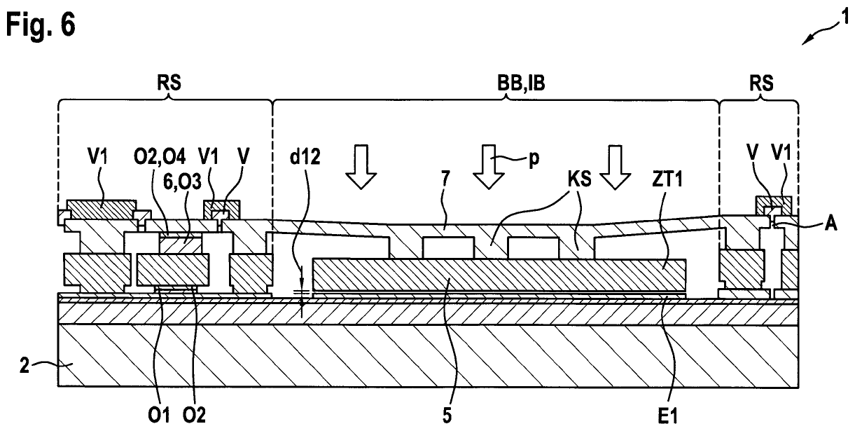

By way of etching accesses A or A′ (see FIG. 5, as a lateral variant of etching access A) laterally outside the movable region(s), a lateral etching access A separated from the diaphragm can be created, and etching of the sacrificial layers can advantageously be effected, from the side and in accelerated fashion, with assistance from elongated trenches G′ between segments of the intermediate carrier (ZT1) and within edge structure RS. Intermediate carrier ZT1 can encompass several movable regions BB constituting segments, which can extend in one direction entirely connectedly to diaphragm MS (“MS” corresponds to diaphragm 7 of FIG. 6), and in another direction can be separated by trenches G.

FIG. 6 is a schematic side view of a sensor device in accordance with an exemplifying embodiment of the present invention.

Once the method steps as shown for example in FIG. 5 have been completed, subsequently, in accordance with FIG. 6, first sacrificial layer O1 and third sacrificial layer 6, O3, and advantageously second sacrificial layer O2 and/or fourth sacrificial layer O4, can be at least partly removed by way of an etching operation through etching accesses A, diaphragm 7 being configured in inner region IB with a region BB movable by a pressure p, and first electrode E1 being spaced at a first spacing d12 away from first intermediate carrier ZT1. The etching operation can propagate from edge structure RS laterally into inner region IB via the previously installed etching conduits or hollow spaces H and H1; depending on the etching duration, sub-regions of the first and/or second sacrificial layer and/or third sacrificial layer 6, O3 and/or of fourth sacrificial layer O4 can remain in place, for example outside inner region IB in edge structure RS. Etching accesses A can furthermore be closed off with a closure material V, for example in order to enclose an advantageously defined internal gas pressure or vacuum in the interior of the sensor device below diaphragm (layer) 7. Closure material V can advantageously form closure plugs V that can be covered with a protective material V1. Closure plugs V can form a closure laterally outside the movable diaphragm, and can form an edge structure RS penetrated by etching conduits (closed off after etching).

Closure material V can be applied or embodied by way of LPCVD or PECVD deposition methods. A silicon-rich nitride layer can be deposited. It is furthermore possible for further functional layers or protective layers to be capable of being deposited onto the diaphragm (layer) and/or onto closure material V, for instance as contact regions, conductor paths, or as diffusion protection or corrosion protection. Protective material V1 can also form a connecting layer between two closure plugs V. A gas-phase HF (hydrofluoric acid) etching method can be used as an etching method. In the inner region, the sacrificial layers under the auxiliary layer can preferably be entirely removed; sacrificial layer(s) O1, O2, and third sacrificial layer O3 and/or fourth sacrificial layers O4 can also be entirely removed in these region.

Because first intermediate carrier ZT1 can be removed toward edge structure RS, a capacitive baseline signal toward the edge in this region, which contributes little to the change in signal, can be very greatly reduced. Contact points KS could, for example, each also extend over a larger planar region; for instance, several contact points are continuous. A stiffening of the diaphragm can be achieved by the connection of diaphragm (layer) 7 and first intermediate carrier ZT1; the capacitive signal can be increased as a result of the stiffening of the diaphragm in this region, since the entire region experiences approximately the same deflection and it is not the case, as with a normal diaphragm, that the maximum deflection can be achieved only in the center. In addition, intermediate carrier ZT1 in the movable region can also extend to its edges, so that this region as well, in which the diaphragm can deflect only a little, can be used for signal generation, and a chip that is very small overall, with a large signal, can be constructed.

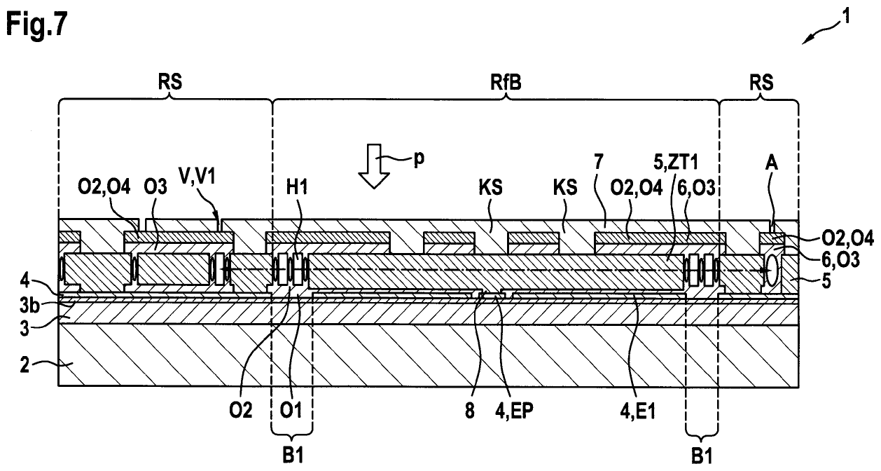

FIG. 7 is a further schematic side view of a sensor device in accordance with an exemplifying embodiment of the present invention.

Sensor device 1 can also encompass at least one reference region RfB, constituting a sub-region of diaphragm 7, in which first intermediate carrier ZT1 encompasses at least one support point 8 that connects first intermediate carrier ZT1 to a region EB electrically separated from first electrode E1, and can brace first intermediate carrier ZT1 on the separated region EB. The geometry of reference region RfB can advantageously differ only slightly from that of the movable region, for instance of FIG. 6, so that reference region RfB and the movable region can advantageously have identical or very similar capacitances, advantageously relating to the respective spacings between first intermediate carrier ZT1 and first electrode E1. Reference region RfB can likewise be configured in inner region IB.

Reference region RfB can furthermore, similarly to the movable region, be sensitive to all environmental and system influences in addition to the pressure that exists in order to move the diaphragm. The other influences can thereby be very effectively compensated for. It is likewise possible for first spacing d12 between first intermediate carrier ZT1 and first electrode E1 in reference region RfB to be selected to be smaller than in the movable region, in particular in such a way that it can correspond approximately to the first spacing in the movable region in the context of an externally applied average or target or working pressure. It is thereby possible for the pressure on the diaphragm to be capable of being effectively and accurately determined by way of an advantageously symmetrical and simple evaluation circuit. The adjustment and configuration of the first spacing in the reference region can be controlled by way of the thickness of the sacrificial layer(s) (or a suitable patterning and combination of the first and the second sacrificial layer) between the first electrode and the auxiliary layer. Patterning in the reference region can be effected upon manufacture in first electrode E1 in order to generate an orifice in first conductive layer 4 inside the reference region, advantageously as far as an insulator layer 3 or 3b thereunder, in order to manufacture electrically separated region EP; support point 8 can then, after the patterning of the first electrode, be configured on the insulator material (not shown). Alternatively thereto, separated region EP itself can also encompass the material of first electrode E1 but can be laterally insulated from the remainder of first electrode E1, advantageously by trenches that can be introduced into first electrode E1, and can be at least at the same potential as first intermediate carrier ZT1 in reference region RfB (in accordance with FIG. 7).

Reference region RfB can be manufactured, for example, analogously to the movable region and simultaneously therewith. A first region B1 can thus surround a first sub-region T1. After application of a first sacrificial layer O1, however, the latter can also be removed over the entire reference region. When a second sacrificial layer O2 is then applied, it can thus be applied directly onto the first conductive layer in reference region RfB, and the thickness of the first spacing in reference region RfB can thereby be adjusted. Second sacrificial layer O2 can then also be patterned over separated region EP, and the auxiliary layer can be connected to separated region EP and disposed in an orifice in that region. Reference region RfB can be located laterally next to the movable region, and first intermediate carrier ZT1 can then be interrupted between the movable region and reference region. The movable region can be disposed behind the reference region in FIG. 7, for example separated by edge structure RS.

An internal gas pressure or a vacuum in the cavity between diaphragm 7 and first electrode E1 can be enclosed, both in reference region RfB and in the movable region (as shown in FIG. 6) thanks to closure plugs V made of closure material V, as also shown in FIG. 6. Because closure plugs V can advantageously be located outside movable region BB, the stress on them can advantageously be less than if they were disposed in movable region BB, since lower bending forces of the diaphragm can act in reference region RfB. Reinforcing layers above diaphragm 7 and closure plug V, which might cause a bimetallic effect on the diaphragm and an increase in its inertia, can thus advantageously be omitted. Closure plugs V can be secured by a terminating cap V1 on diaphragm (layer) 7; the latter can be electrically conductive.

The overall result of the present embodiment is that a small spacing between first electrode E1 and the diaphragm, in particular first intermediate carrier ZT1, can be achieved; and diaphragm 7 itself can be made particularly thin because of the stiffening effect of first intermediate carrier ZT1. In addition, etching accesses (A in FIG. 5) can be implemented alongside the movable diaphragm (layer) and can eliminate additional closure material in the diaphragm region. Diaphragm 7 can thus be made of only one material and can be configured homogeneously (for example, it can be configured without etching accesses in the movable region). A comparatively smaller sensor is therefore achievable, and because of its dimensions it can exhibit a large capacitive signal change relative to a baseline signal, for instance from an activation system.

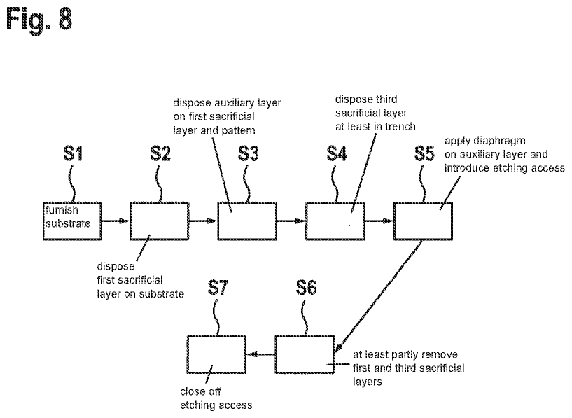

FIG. 8 schematically depicts method steps of a method for manufacturing a sensor device in accordance with an exemplifying embodiment of the present invention.

In the method for manufacturing a sensor device, a substrate is furnished S1; at least one first sacrificial layer is disposed S2 on the substrate; an auxiliary layer is disposed S3 on the at least first sacrificial layer, and the auxiliary layer is patterned in such a way that at least one trench as far as the at least one first sacrificial layer is introduced into the auxiliary layer, the trench being located laterally inside an edge region, the edge region representing at least in part a lateral border on the substrate; a third sacrificial layer is disposed S4 at least in the trench; a diaphragm is applied S5 on the auxiliary layer and at least one etching access is introduced into the diaphragm in the edge region; the at least first sacrificial layer and the third sacrificial layer are at least partly removed S6 laterally inside the edge region by way of an etching operation through the at least one etching access; and the at least one etching access is closed off S7 with a closure material, and a defined pressure is enclosed.

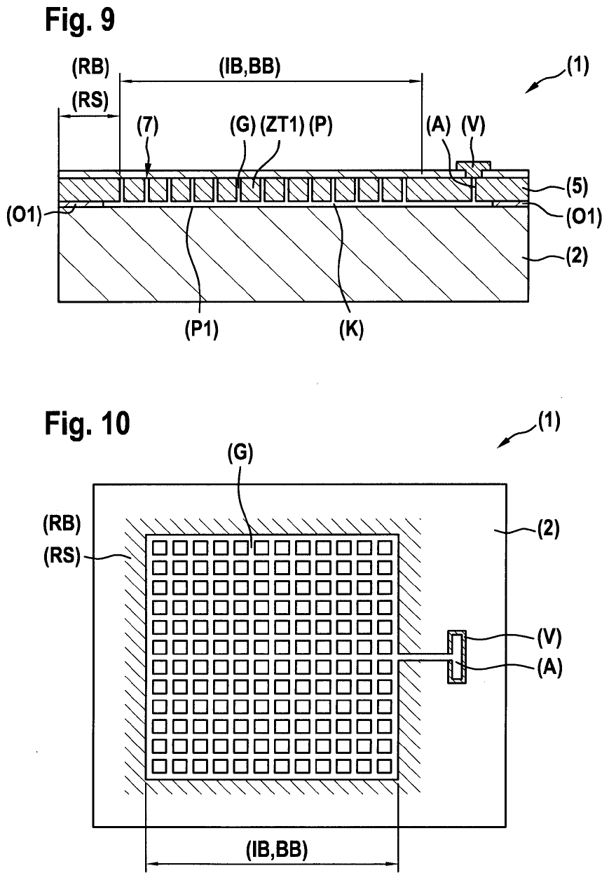

FIG. 9 is a schematic side view of a sensor device in accordance with a further exemplifying embodiment of the present invention.

FIG. 9 shows a simple baseline version of the sensor device, the latter having at least a substrate 2; and an edge region RB, RS that is disposed on substrate 2 and encompasses and laterally delimits an inner region IB above substrate 2. The sensor device also has a diaphragm 7 that is anchored on edge structure RS and at least partly spans inner region IB, diaphragm 7 encompassing in inner region IB at least one region BB, movable by a pressure p, which encloses a cavity K between diaphragm 7 and substrate 2; and a first intermediate carrier ZT1 that extends in movable region BB below diaphragm 7 and is connected to diaphragm 7 and has at least one trench G.

Etching through a media access A, and subsequent closure V beyond cavity K, can be accelerated by the trenches, which can have part of the material of third sacrificial layer O3. Etching can occur only until a residue of first sacrificial layer O1 remains behind in edge region RS and can form edge structure RS, RB of the cavity. Optionally, the third sacrificial layer can also be applied onto the upper side of auxiliary layer 5 and can be subsequently removed by etching (as in FIGS. 1 to 7) or can partly remain. In the example shown in FIG. 9, the third sacrificial layer can be back-thinned (planarized) above the trench before diaphragm 7 is applied.

FIG. 10 is a schematic plan view of a sensor device in accordance with a further exemplifying embodiment of the present invention.

FIG. 10 is a plan view of sensor device 1 of FIG. 9. Trenches G can form square structures laterally inside edge region RS, i.e. for instance in movable region BB, and etching access A can be located laterally outside the latter. Etching from access A via inner region IB can be accelerated by way of the trenches.

Although the present invention has been described in the present case entirely with reference to the preferred exemplifying embodiment, it is not limited thereto but is instead modifiable in many ways.

1-26. (canceled)

27. A sensor device, comprising:
at least one substrate;
an edge region that is disposed on the substrate and laterally delimits an inner region above the substrate;
a diaphragm that is anchored on the edge region and at least partly spans the inner region, the diaphragm encompassing in the inner region at least one moveable region which is movable by way of a pressure and which encloses a cavity between the diaphragm and the substrate; and
at least one first intermediate carrier that extends in the movable region below the diaphragm and is connected to the diaphragm, and has at least one trench.

28. The sensor device as recited in claim 27, further comprising a media access having a closure, which is connected to the cavity and is disposed outside the movable region of the diaphragm and encloses a defined pressure in the cavity and in the media access.

29. The sensor device as recited in claim 27, wherein the edge region encompasses at least one etching access conduit that is connected to the cavity.

30. The sensor device as recited in claim 27, wherein at least one electrically conductive layer constituting a first electrode is disposed on the substrate and between the substrate and the first intermediate carrier, and is electrically insulated from the substrate.

31. The sensor device as recited in claim 27, wherein the first intermediate carrier is fastened at contact points on the diaphragm in the movable region.

32. The sensor device as recited in claim 27, wherein the first intermediate carrier has a complete mechanical connection to the diaphragm in a subregion and in a first direction, and over an entire width in the first direction.

33. The sensor device as recited in claim 27, wherein the first intermediate carrier is segmented into individual intermediate-carrier elements in a second direction, and the individual elements are embodied continuously in a first direction that deviates from the second direction.

34. The sensor device as recited in claim 27, wherein the diaphragm encompasses at least one reference region constituting a sub-region in which the first intermediate carrier encompasses at least one support point that mechanically connects the first intermediate carrier to the substrate.

35. The sensor device as recited in claim 27, wherein diaphragm encompasses an equal number of reference regions and movable regions, which are interconnected to one another as a half or full Wheatstone bridge.

36. The sensor device as recited in claim 27, wherein the diaphragm is electrically contacted via the edge region.

37. The sensor device as recited in claim 27, wherein at least one of the at least one trench has a width which is less than a height of the first intermediate carrier.

38. The sensor device as recited in claim 31, wherein a spacing from the edge region to a nearest one of the contact points is at least 10% of a planar region of extent of the diaphragm, the region of extent corresponding to a diameter when the diaphragm is circular or corresponding to a length of a shorter side edge in when the diaphragm is rectangular.

39. The sensor device as recited in claim 27, wherein the at least one first intermediate carrier includes at least two first intermediate carriers which extend in the movable region below the diaphragm and are connected to the diaphragm, the at least two first intermediate carriers being separated from one another by a trench.

40. A method for manufacturing a sensor device, comprising the following steps:
furnishing a substrate;
disposing at least one first sacrificial layer on the substrate;
disposing an auxiliary layer on the at least first sacrificial layer, and patterning the auxiliary layer in such a way that at least one trench is introduced in the auxiliary layer as far as the at least first sacrificial layer, the trench being located laterally within an edge region, the edge region representing at least in part a lateral border on the substrate;
disposing a third sacrificial layer at least in the trench;
applying a diaphragm onto the auxiliary layer and introducing at least one etching access into the diaphragm in the edge region;
at least partly removing the at least first sacrificial layer and the third sacrificial layer laterally inside the edge region by way of an etching operation through the at least one etching access;
closing off the at least one etching access with a closure material and enclosing a defined pressure;
patterning the first conductive layer in such a way that in a first region, the first conductive layer is removed and the first region delimits a first sub-region of the first conductive layer, the first conductive layer forming a first electrode in the first sub-region;
disposing the first sacrificial layer on the first conductive layer and in the first region, and patterning the at least one first sacrificial layer in such a way that the first conductive layer is exposed in a second region, and the second region is located laterally outside the first sub-region, the second region delimiting an inner region;
disposing the auxiliary layer on the at least first sacrificial layer and in the second region, and patterning the auxiliary layer in such a way that orifices as far as the at least first sacrificial layer, which are located above the first region and in a third region, are introduced in the auxiliary layer, the third region being located laterally outside the first sub-region and the second region, the auxiliary layer forming a first intermediate carrier in the first sub-region;
disposing the third sacrificial layer on the auxiliary layer in the first region and the third region, and patterning the third sacrificial layer in such a way that the orifices are configured above the second region and above the first sub-region through the third sacrificial layer and as far as the auxiliary layer;
disposing a diaphragm on the third sacrificial layer and in the orifices in the first sub-region and in the second region, and introducing the etching access into the diaphragm in the third region, the auxiliary layer forming in the second region the edge region in which the diaphragm is anchored, and the diaphragm forming, in the orifices in the first sub-region of the third sacrificial layer, contact points between the diaphragm and the first intermediate carrier; and
at least partly removing the at least first sacrificial layer and the third sacrificial layer by an etching operation through the etching access, the diaphragm being configured in the inner region with a moveable region that is movable by a pressure, and the first electrode being spaced at a first spacing away from the first intermediate carrier.

41. The method as recited in claim 40, wherein the third sacrificial layer is also disposed on the auxiliary layer, and the third sacrificial layer is patterned in such a way that the orifices as far as the auxiliary layer are introduced laterally inside the edge region, and the orifices being filled with a material of the diaphragm.

42. The method as recited in claim 40, wherein before placement of the first sacrificial layer, the first conductive layer is applied on the substrate and is patterned laterally inside the edge region.

43. The method as recited in claim 40, wherein the etching access is connected, laterally and below the diaphragm, at least to the first sacrificial layer and/or the third sacrificial layer.

44. The method as recited in claim 40, wherein a second sacrificial layer or fourth sacrificial layer is disposed on the first sacrificial layer and/or on the third sacrificial layer, and is patterned and removed in the same regions with the first sacrificial layer and/or with the third sacrificial layer.

45. The method as recited in claim 40, wherein the auxiliary layer is completely removed in the third region and/or in the first region.

46. The method as recited in claim 40, wherein the diaphragm is configured with a reference region which represents a sub-region of the diaphragm and in which the auxiliary layer is configured with at least one support point that connects the auxiliary layer to a region electrically separated from the first conductive layer and braces the auxiliary layer on it.

47. The method as recited in claim 40, wherein trenches, by way of which a separation into at least two first intermediate carriers connected to the diaphragm is effected, are generated at least in a first sub-region into the auxiliary layer or into the intermediate carriers.

48. The method as recited in claim 47, wherein trenches, by way of which a separation of the at least two first intermediate carriers into several segments is effected, are generated at least in a first sub-region into the auxiliary layer or into the at least two intermediate carriers, provision being made in that those segments have no direct mechanical connection to one another.
